(19) United States
(12) Patent Application Publication
(10) Pub. No.: US 2017/0202104 A1
(43) Pub. Date: Jul. 13, 2017

(54) CARBON-COATED COPPER FOIL FOR HEAT DISSIPATION

(71) Applicant: Cheng-Kuang Lin, New Taipei City (TW)

(72) Inventor: Cheng-Kuang Lin, New Taipei City (TW)

(21) Appl. No.: 14/991,006

(22) Filed: Jan. 8, 2016

(51) Int. Cl. H05K 7/20

(52) U.S. Cl. CPC H05K 7/2039

(57) ABSTRACT

This invention is related to a carbon-coated copper foil for heat dissipation, which comprising a copper foil, a metal-dielectric layer, and a carbon film. The copper foil is formed with a first rough surface, and the metal-dielectric layer is coated on the first rough surface of the copper foil. The metal-dielectric layer is formed with a second rough surface along with the first rough surface, and the carbon film is embedded and coated on the second rough surface. Accordingly, the rough surfaces of the copper foil and the metal-dielectric layer make the carbon atoms attach firmly on the copper foil. Furthermore, the carbon film formed by bonded carbon atoms has high thermal conductivity, so it can dramatically improve the effect of the heat dissipation of the electronics and extend the use life of the electronics.

### BACKGROUND OF THE INVENTION

Field of the Invention

The present invention relates to a carbon-coated copper foil for heat dissipation. More particularly, the carbon-coated copper foil has high thermal conductivity and is convenient to be processed.

Description of Related Art

With the rapidly development of the electronic industry, the electronic devices are more and more popular, such as personal computer, mobile phone, multifunction printer, and GPS navigation etc. The volume of the electronic components and the electronics tend to be developed into thinner, lighter, and smaller, in addition, the function of the electronic components and the electronics are more and more and powerful.

With higher of the integration density of the electronics, the amount of the electronic components in unit area is geometrically increased, so the heat dissipation becomes an important issue. If the heat is not dissipated immediately, it results that the work temperature of the components is raised, in serious, the electronic components are loss of function, directly affecting the life and the reliability of all high precision equipment which are assembled with the electronic components. Therefore, how to dissipate heat has become a bottleneck of the integration and miniaturization of the electronics.

The thermally conductive silicone is the traditional material for heat dissipation. The thermally conductive silicone is compressible, but comparison with metal such as copper, the thermal conductivity of the thermally conductive silicone is poor, it is usually used with the fan. When it requires to rapidly reduce temperature and the space is limited, it seems powerless. Therefore, the carbon layer is connected to the bottom of the copper, achieving the effect of heat dissipation. Please refer to the CN Patent application with the Publication No. CN103476227 A, “Copper-carbon composite heat sink and process for making thereof”, it discloses that the copper-carbon composite heat sink is formed of a copper foil, which both sides are coated with a thermally conductive carbon layer. The thickness of the copper foil is 0.02-0.25 mm, the thickness of the thermally conductive carbon layer is 0.015-0.03 mm, and the thickness of the copper-carbon composite heat sink is 0.08-0.3 mm. The thermally conductive carbon layer is consist of 100 parts by weight of graphene or single-walled carbon nanotube and 1-50 parts by weight of adhesive. The specific surface area of the graphene is 500-1000 m²/g. The particle diameter of single-walled carbon nanotube is 5 nm. The adhesive is polyvinylidene fluoride, polyvinyl pyrrolidone, polyethylene glycol, polyvinyl alcohol, or the combination of thereof. A process for making the copper-carbon composite heat sink comprises the steps as below. (1) The adhesive is dissolved in an organic solvent to obtain an organic adhesive solution. (2) Graphene or carbon nanotube is mixed with the organic adhesive solution to obtain a mixture. (3) The mixture is sonicated to disperse for 0.5-1 hour and then stirred to disperse at 1500-3000 rpm for 1-5 hours to obtain a uniform mixture. (4) The uniform mixture is coated on both sides of a copper foil, and under inert gas protection, it is cured to obtain the copper-carbon composite heat sink, wherein the curing temperature is 50-200° C. and the curing time is 10-100 min.

In the foregoing CN Patent application with the Publication No. CN103476227 A, “Copper-carbon composite heat sink and process for making thereof”, it achieves the effect that the carbon containing material is coated on the bottom of the copper foil, but the coating method is that the carbon containing material is made into an organic solution with adhesive and solvent, then it is coated and cured under inert gas protection to form the copper-carbon composite heat sink. The carbon containing material which is coated only by adhesive or solvent is not only detached easily, but also unstable to attach with the copper foil. The carbon layer is easily detached from the copper foil. Moreover, the carbon containing materials are connected with each other by the adhesive or solvent, resulting in decreasing the conductivity of the carbon containing materials, sharply decreasing the effect of heat conductivity.

### SUMMARY OF THE INVENTION

Accordingly, in view of the foregoing structure and process of the copper foil coated with the carbon layer, the connection between the copper material and carbon layer is poor, resulting in reducing the thermal conductivity and high cost, so that is not cost-effective.

Therefore, the object of the present invention is related to a carbon-coated copper foil for heat dissipation. More particularly, the carbon-coated copper foil has well thermal conductivity.

For the above object, a carbon-coated copper foil for heat dissipation comprises a copper foil, a metal-dielectric layer, and a carbon film. The copper foil is formed with a first rough surface, and the metal-dielectric layer is coated on the first rough surface of the copper foil. The metal-dielectric layer is formed with a second rough surface along with the first rough surface. The carbon film is embedded and coated on the second rough surface of the metal-dielectric layer, wherein the carbon film is formed by continuously depositing bonded carbon atoms.

According to an embodiment of the present invention, the metal-dielectric layer is made of Ni, Cr, or Ti.

According to an embodiment of the present invention, the first rough surface of the copper foil is formed by plasma shock wave.

According to an embodiment of the present invention, the carbon film is a two-dimensional carbon cluster.

According to an embodiment of the present invention, the carbon film is a three-dimensional carbon cluster.

The actual processing method of the foregoing carbon-coated copper foil is described as below. A rough surface is formed on the surface of the copper foil by plasma shock wave, then the metal-dielectric layer is formed on the rough surface of the copper foil, and the carbon atoms are embedded in the metal-dielectric layer to deposit on the rough surface of the copper foil to form a carbon film. Accordingly, the rough surfaces of the copper foil and the metal-dielectric layer make the carbon atoms attach firmly on the copper foil. Furthermore, the carbon film formed by bonded carbon atoms has well tightness and high thermal conductivity, so it can dramatically improve the effect of the heat dissipation of the electronics and extend the use life of the electronics.

According to an embodiment of the present invention, the both sides of the copper foil are formed with the rough surfaces and are coated with the metal-dielectric layers. The carbon atoms are deposited and attached on the metal-dielectric layers to promote the efficiency of the carbon-coated copper foil of the present invention, promoting its competitiveness.

According to an embodiment of the present invention, the metal-dielectric layer is made of Ni, Cr, or Ti.

According to an embodiment of the present invention, the carbon film is a two-dimensional or a three-dimensional carbon cluster.

### BRIEF DESCRIPTION OF THE DRAWINGS

FIG. 1 is a sectional view of a carbon-coated copper foil according to an embodiment of the present invention; and

FIG. 2 is a sectional view of a carbon-coated copper foil according to another embodiment of the present invention.

### DETAILED DESCRIPTION OF THE PREFERRED EMBODIMENT

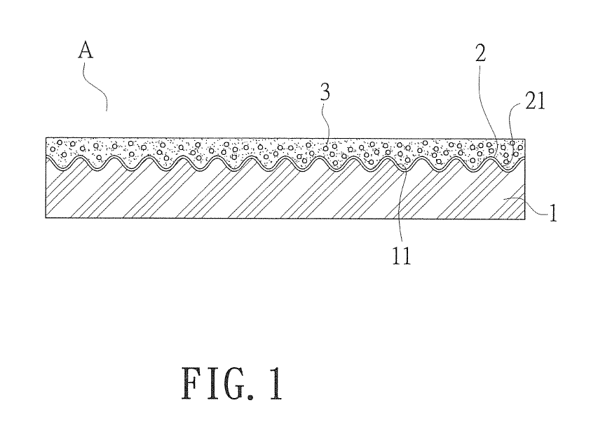

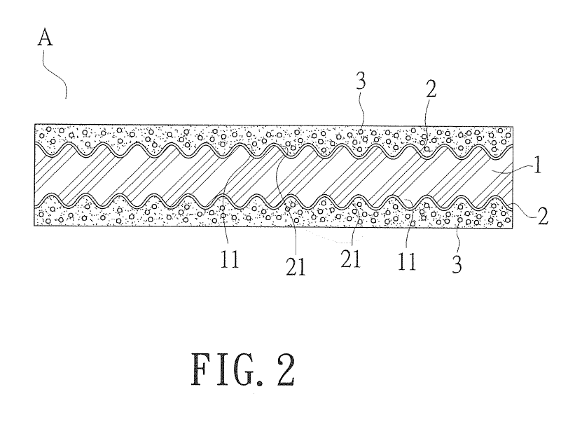

First, please refer to FIG. 1 and FIG. 2, which are sectional views of a carbon-coated copper foil according to different embodiments of the present invention. The carbon-coated copper foil comprises a copper foil 1, at least one metal-dielectric layer 2, and at least one carbon film 3.

The copper foil 1 is formed with a first rough surface 11 at least one surface by plasma shock wave.

The metal-dielectric layer 2 is coated on the surface of the copper foil 1 and formed with a second rough surface 21 along with the first rough surface 11.

The carbon film 3 is embedded and coated on the second rough surface 21 of the metal-dielectric layer 2, and the carbon film 3 is formed by continuously depositing bonded carbon atoms.

The actual processing method of the carbon-coated copper foil A is described as below.

a. prepare copper foil: A copper foil 1 is put into a vacuum-chamber;

b. coarsen copper foil: then, the gas is passed into the vacuum-chamber, and the electric field is generated to make the gas in the vacuum-chamber become plasma. Under guidance of the magnetic field, the positively charged plasma rushes at high speed toward the copper foil 1 which is determined as cathode to form a first rough surface 11 at one surface of the copper foil 1;

c. coat the dielectric layer: the metal gas which containing Ni, Cr, or Ti is passed into the vacuum-chamber, and the electric field is generated again to make Ni, Cr, or Ti in the metal gas to be positively charged. Under guidance of the magnetic field, the positively charged Ni, Cr, or Ti rushes at high speed toward the copper foil 1 which is determined as cathode to form a metal-dielectric layer 2 at the first rough surface 11 of the copper foil 1. And the metal-dielectric layer 2 is formed with a second rough surface 21 along with the first rough surface 11.

d. deposit carbon atom: a mixture gas containing carbon atoms is passed into the vacuum-chamber, and the electric field is generated again to make the carbon atoms to be positively charged. Under guidance of the magnetic field, the positively charged carbon atoms rush at high speed toward the copper foil 1 which is determined as cathode to embed in the second rough surface 21 of the metal-dielectric layer 2 and continuously deposit on the metal-dielectric layer 2 and bond together to form a two-dimensional carbon cluster film and even a three-dimensional carbon cluster film on the metal-dielectric layer 2.

e. turn-over and forming: the other surface 11 of the copper foil 1 is processed by the foregoing step b, c, and d to form another rough surface on that surface 11 of the copper foil 1. Then, a metal-dielectric layer 2 is coated on and the carbon atoms are evenly coated on the surface of the metal-dielectric layer 2 to continuously deposit on the metal-dielectric layer 2 for forming a carbon cluster film. Accordingly, a carbon-coated copper foil A with high purity carbon and low resistance is formed.

Therefore, the carbon film 3 can be firmly coated on the copper foil 1 by the foregoing processing method. Furthermore, the carbon film 3 is formed by the bonded carbon atoms, so the carbon film has well tightness and is not easily detached. Moreover, the carbon film purely formed by the carbon atoms has well conductivity and electric conductivity. Accordingly, the carbon-coated copper foil A of the present invention can dramatically increase the mechanical strength of the copper foil 1, the well thermal conductivity of the carbon-coated copper foil promote the heat dissipation of the electric product and the electric element which are assembled with the carbon-coated copper foil, further extending the use life of the electronics.

According to the above description and embodiments, the carbon-coated copper foil of the present invention has the advantages as following:

1. In the carbon-coated copper foil of the present invention, when the carbon atoms are coated on the copper foil via the metal-dielectric layer, the rough surface of the copper foil make the carbon atoms to attach firmly on the copper foil by embedding the carbon atoms on the surfaces of the copper foil and the metal-dielectric layer. Accordingly, the carbon film is uneasily peeled from the surface of the copper foil, ensuring the increase of the mechanical strength of the copper foil.

2. In the carbon-coated copper foil of the present invention, the carbon film is formed by continuously depositing bonded carbon atoms, so the carbon film has well tightness due to the bonded structure between the carbon atoms. Moreover, the carbon film purely formed by the carbon atoms has well electric conductivity. Therefore, the carbon-coated copper foil of the present invention can dramatically increase the mechanical strength of the copper foil, and the well thermal conductivity of the carbon-coated copper foil promote the heat dissipation of the electric product and the electric element which are assembled with the carbon-coated copper foil, further extending the use life of the electronics.

3. In the carbon-coated copper foil of the present invention, the both sides of the copper coil are formed with the rough surfaces and coated by the metal-dielectric layers and the carbon layers, so the use efficiency of the carbon-coated copper foil is doubled increased, raising the yield of the carbon-coated copper foil and its competitiveness.

What is claimed is:

1. A carbon-coated copper foil for heat dissipation, comprising:
a copper foil, formed with a first rough surface;
a metal-dielectric layer, coated on the first rough surface of the copper foil and formed with a second rough surface along with the first rough surface; and
a carbon film, embedded and coated on the second rough surface of the metal-dielectric layer, wherein the carbon film is formed by continuously depositing bonded carbon atoms.

2. The carbon-coated copper foil for heat dissipation as claim 1, wherein the metal-dielectric layer is made of Ni, Cr, or Ti.

3. The carbon-coated copper foil for heat dissipation as claim 1, wherein the carbon film is a two-dimensional carbon cluster.

4. The carbon-coated copper foil for heat dissipation as claim 1, wherein the carbon film is a three-dimensional carbon cluster.

5. The carbon-coated copper foil for heat dissipation as claim 2, wherein the first rough surface is formed by plasma shock wave.

6. The carbon-coated copper foil for heat dissipation as claim 2, wherein the carbon film is a two-dimensional carbon cluster.

7. The carbon-coated copper foil for heat dissipation as claim 2, wherein the carbon film is a three-dimensional carbon cluster.

8. The carbon-coated copper foil for heat dissipation as claim 5, wherein the carbon film is a two-dimensional carbon cluster.

9. The carbon-coated copper foil for heat dissipation as claim 5, wherein the carbon film is a three-dimensional carbon cluster.
